(19) United States
(12) Patent Application Publication
(10) Pub. No.: US 2026/0353717 A1
(43) Pub. Date: Nov. 5, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Hsiao-Hua Hung, Hsinchu City (TW); Ming-Yen Chuang, Hsinchu City (TW); Yun-Feng Kao, New Taipei City (TW); Kuo-Chang Chiang, Hsinchu City (TW); Tsung-Han Wu, New Taipei City (TW); Chih-Yu Chang, New Taipei City (TW)

(21) Appl. No.: 19/198,652

(22) Filed: May 5, 2025

(51) Int. Cl. H10D 62/10; H10D 30/01; H10D 30/63; H10D 62/17; H10D 84/01; H10D 84/83

(52) U.S. Cl. CPC H10D 62/102; H10D 30/025; H10D 30/63; H10D 62/115; H10D 62/292; H10D 84/0128; H10D 84/016; H10D 84/837

(57) ABSTRACT

The present disclosure, in some embodiments, relates to an integrated chip. The integrated chip includes a lower source/drain over a substrate, a channel arranged over the lower source/drain, and an upper source/drain over the channel. Gate electrodes are arranged along opposing sides of the channel. The channel includes a channel material laterally surrounding an insulating core disposed over the lower source/drain. The channel material laterally separates the insulating core from the gate electrodes.

### BACKGROUND

Modern-day integrated chips comprise millions or billions of semiconductor devices formed on a semiconductor substrate (e.g., a silicon substrate). The semiconductor devices are electrically coupled together by interconnects. The interconnects comprise interconnect wires and interconnect vias disposed within a dielectric structure over a semiconductor substrate. By using interconnects to electrically couple the semiconductor devices together, the semiconductor devices are able to perform logical functions that enable operation of an integrated chip.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 illustrates some embodiments of an integrated chip structure having a vertical transistor with a channel comprising a channel material surrounding an insulating core.

FIG. 2 illustrates some additional embodiments of an integrated chip structure having a vertical transistor with a channel comprising a channel material surrounding an insulating core.

FIG. 3 illustrates some additional embodiments of an integrated chip structure having a vertical transistor with a channel comprising a channel material surrounding an insulating core including a channel insulating material.

FIGS. 4A-4B illustrate some additional embodiments of integrated chip structures having a vertical transistor with a channel comprising a channel material surrounding an insulating core including an air-gap.

FIG. 5 illustrates some additional embodiments of an integrated chip structure having a vertical transistor with a channel comprising a channel material surrounding an insulating core including a channel insulating material and an air-gap.

FIG. 6 illustrates some additional embodiments of an integrated chip structure having a vertical transistor with a channel comprising a channel material surrounding an insulating core.

FIGS. 7A-7B illustrate some embodiments of an integrated chip memory structure having a vertical transistor with a channel comprising a channel material surrounding an insulating core.

FIGS. 8-17 illustrate cross-sectional views of some embodiments of a method of forming an integrated chip structure having a vertical transistor with a channel comprising a channel material surrounding an insulating core including a channel insulating material.

FIGS. 18-27 illustrate cross-sectional views of some additional embodiments of a method of forming an integrated chip structure having a vertical transistor with a channel comprising a channel material surrounding an insulating core including an air-gap.

FIG. 28 illustrates a flow diagram of some embodiments of a method of forming an integrated chip structure having a vertical transistor with a channel comprising a channel material surrounding an insulating core.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Vertical transistors (e.g., vertical field effect transistors (VFETs)) are transistors that have a channel structure extending between source and drain regions along a direction that is perpendicular to an upper surface of an underlying semiconductor substrate. Vertical transistors often have a source region and a drain region stacked onto one another, so as to allow current to flow vertically. Vertical transistors allow for the scale of transistors to shrink, thereby improving a density of integrated chip devices and a performance of integrated chips. The advantages realized by vertical transistors have applications in power electronics (e.g., with handling higher currents and voltages efficiently), high-frequency applications (e.g., due to fast switching capabilities), and the like.

However, it has been appreciated that the structure and/or materials used in vertical transistors may also lead to several challenges. For example, the materials used in vertical transistors may be susceptible to higher leakage currents, increased power consumption, and reduced energy efficiency. Some materials might also increase unwanted parasitic capacitance, thereby inducing limiting switching speed and high-frequency performance. Additionally, the materials may be susceptible to thermal damage that can affect thermal stability and performance in high-power applications. These challenges may suppress the effectiveness of vertical transistors in high-efficiency and/or low-power settings.

The present disclosure relates to an integrated chip structure comprising a vertical transistor having a channel that includes a channel material surrounding an insulating core. In some embodiments, the integrated chip structure comprises a lower source/drain over a substrate, a channel arranged over the lower source/drain, and an upper source/drain over the channel. Gate structures are arranged along opposing sides of the channel. The channel comprises a channel material laterally surrounding an insulating core disposed over the lower source/drain. The channel material laterally separates the insulating core from the gate structures. The insulating core of the channel improves insulating properties of the channel and thereby reduces leakage currents between the lower source/drain and the upper source/drain. The reduced leakage can reduce an overall power consumption (e.g., improve an overall energy efficiency) of an integrated chip structure.

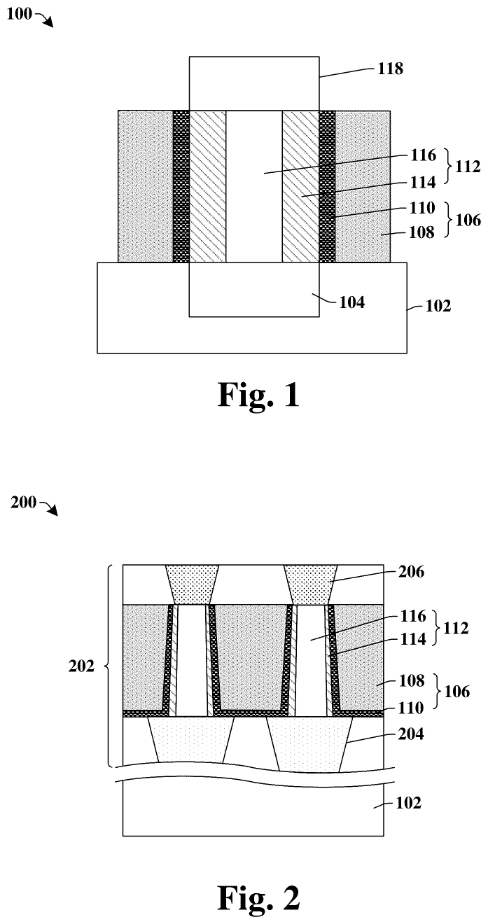

FIG. 1 illustrates some embodiments of an integrated chip structure 100 having a vertical transistor with a channel comprising a channel material surrounding an insulating core.

The integrated chip structure 100 comprises a vertical transistor having a lower source/drain 104 vertically separated from an upper source/drain 118 by a channel 112. In some embodiments, the lower source/drain 104 may be disposed on, over, and/or within a substrate 102. One or more gate structures 106 are arranged along one or more sides of the channel 112 and above the lower source/drain 104. The one or more gate structures 106 respectively include a gate electrode 108 and a gate dielectric 110. The gate dielectric 110 separates the gate electrode 108 from the channel 112.

The channel 112 comprises a channel material 114 and an insulating core 116. The insulating core 116 is laterally surrounded on opposing sides by the channel material 114, so that the channel material 114 separates opposing sides of the insulating core 116 from the one or more gate structures 106. The insulating core 116 of the channel 112 improves insulating properties of the channel 112 and therefore reduces leakage currents between the lower source/drain 104 and the upper source/drain 118. The reduced leakage currents can reduce an overall power consumption (e.g., improve an overall energy efficiency) of an integrated chip structure 100.

Furthermore, the insulating core 116 can also reduce parasitic capacitances and improve thermal properties of the channel 112. For example, the insulating core 116 can decrease a parasitic capacitance between neighboring gate structures, thereby allowing for faster switching speeds and improved high-frequency performance of the vertical transistor. The insulating core 116 can also decrease thermal transfer between different segments of the channel material 114, thereby increasing a thermal stability and ensuring better performance of the vertical transistor in high-temperature or high-power applications. The increased thermal stability can reduce a risk of overheating and improve a reliability and longevity of devices. The improvement of electrical and thermal characteristics can enable further miniaturization of electronic components and allow for more compact and efficient electronic devices.

FIG. 2 illustrates some additional embodiments of an integrated chip structure 200 having a vertical transistor with a channel comprising a channel material surrounding an insulating core.

The integrated chip structure 200 comprises an inter-level dielectric (ILD) structure 202 disposed over a substrate 102. The ILD structure 202 includes a plurality of ILD layers stacked onto one another. Vertical transistors are arranged within the ILD structure 202. The vertical transistors includes lower source/drains separated from upper source/drains by a plurality of channels 112.

In some embodiments, the lower source/drains comprise a plurality of lower source/drain contacts 204 disposed within the ILD structure 202 and the upper source/drains comprise a plurality of upper source/drain contacts 206 disposed within the ILD structure 202 above the lower source/drain contacts 204. In some embodiments (not shown), one or more conductive interconnects (e.g., conductive contacts, interconnect wires, and/or interconnect vias) may be disposed within the ILD structure 202 between the plurality of lower source/drain contacts 204 and the substrate 102. In some embodiments, the plurality of lower source/drain contacts 204 may comprise source contacts and the plurality of upper source/drain contacts 206 may comprise drain contacts. In other embodiments, the plurality of lower source/drain contacts 204 may comprise drain contacts and the plurality of upper source/drain contacts 206 may comprise source contacts.

A plurality of gate structures 106 are arranged within the ILD structure 202 vertically between the plurality of lower source/drain contacts 204 and the plurality of upper source/drain contacts 206. The plurality of gate structures 106 are arranged along opposing sides of the plurality of lower source/drain contacts 204. For example, in some embodiments the plurality of gate structures 106 may straddle opposing outermost sidewalls of the plurality of lower source/drain contacts 204. The plurality of gate structures 106 include a gate electrode 108 and a gate dielectric 110 extending along outer surfaces of the gate electrode 108. In some embodiments, the gate dielectric 110 wraps around sidewalls and a bottommost surface of the gate electrode 108. In some embodiments, the gate dielectric 110 vertically separates the plurality of lower source/drain contacts 204 from the gate electrode 108.

The plurality of channels 112 are arranged vertically between the plurality of lower source/drain contacts 204 and the plurality of upper source/drain contacts 206 and laterally between neighboring ones of the plurality of gate structures 106. In some embodiments, the gate dielectric 110 laterally separates the gate electrode 108 from the plurality of channels 112 disposed along opposing sides of the gate electrode 108. The plurality of channels 112 respectively comprise a channel material 114 and an insulating core 116. The insulating core is laterally surrounded on opposing sides by the channel material 114, so that the channel material 114 separates opposing sides of the insulating core 116 from the plurality of gate structures 106. In some embodiments, the plurality of channels 112 may respectively have a width that decreases as a height over the substrate 102 increases and the plurality of gate structures 106 may respectively have a width that increases as a height over the substrate 102 increases.

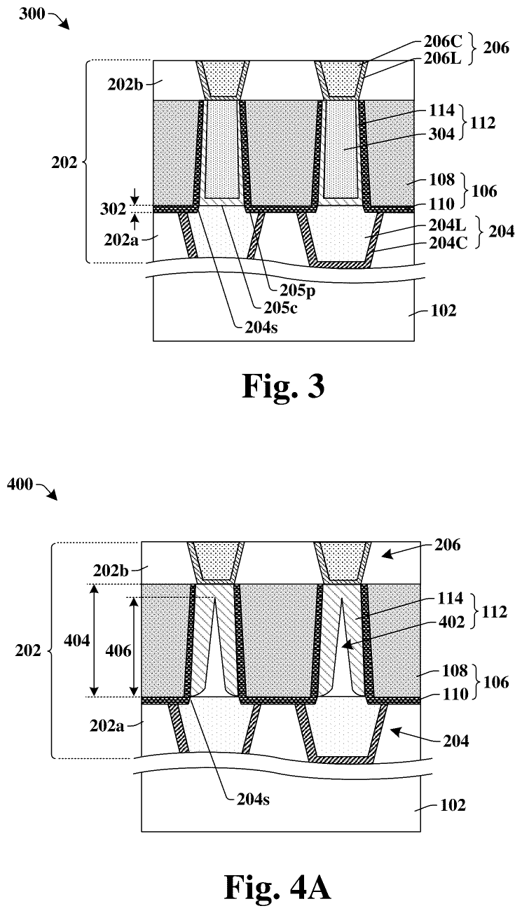

FIG. 3 illustrates some additional embodiments of an integrated chip structure 300 having a vertical transistor with a channel comprising a channel material surrounding an insulating core including a channel insulating material.

The integrated chip structure 300 comprises an ILD structure 202 disposed over a substrate 102. The ILD structure 202 includes a plurality of ILD layers 202a-202b stacked onto one another. For example, the ILD structure 202 may comprise a first ILD layer 202a and a second ILD layer 202b stacked onto the first ILD layer 202a. The plurality of ILD layers 202a-202b may respectively comprise silicon dioxide, silicon oxynitride (SiN), silicon carbon nitride (SiCN), titanium oxide (TiOx), amorphous silicon (a-Si), amorphous carbon (a-C), carbon doped silicon oxide (SiCOH), phosphosilicate glass (PSG), borophosphosilicate glass (BPSG), borosilicate glass (BSG), fluorosilicate glass (FSG), undoped silicate glass (USG), and/or the like. In some embodiments, the first ILD layer 202a may have a thickness that is in a range of between approximately 1 nanometer (nm) and approximately 150 nm, between approximately 50 nm and approximately 150 nm, or other similar values.

A plurality of lower source/drain contacts 204 are disposed within the ILD structure 202. In some embodiments, the plurality of lower source/drain contacts 204 respectively comprise a central upper surface 205c and a peripheral upper surface 205p laterally surrounding the central upper surface 205c. The peripheral upper surface 205p is a non-zero distance 302 vertically below the central upper surface 205c. The plurality of lower source/drain contacts 204 have a larger height along the central upper surface 205c than along the peripheral upper surface 205p. In some embodiments, the plurality of lower source/drain contacts 204 respectively comprise a bottommost surface with a first width, a topmost surface with a second width, and a third width vertically between the topmost surface and the bottommost surface. In such embodiments, the third width may be larger than the first width and the second width. In some embodiments, the peripheral upper surface 205p may be substantially symmetric about the central upper surface 205c. In other embodiments, the peripheral upper surface 205p may be asymmetric about the central upper surface 205c (e.g., so that the peripheral upper surface 205p along a first side of the central upper surface 205c has a larger width than the peripheral upper surface 205p along a second side of the central upper surface 205c).

The plurality of lower source/drain contacts 204 may comprise a lower conductive fill 204C surrounded by a lower source/drain liner 204L. In some embodiments, the lower source/drain liner 204L may comprise one or more of molybdenum (Mo), titanium (Ti), tantalum nitride (TaN), titanium nitride (TiN), tungsten (W), aluminum (Al), chromium (Cr), nickel (Ni, tantalum (Ta), ruthenium (Ru), cobalt (Co), copper (Cu), and/or the like. A. In some embodiments, the lower conductive fill 204C may comprise one or more of molybdenum (Mo), titanium (Ti), tungsten (W), tantalum nitride (TaN), titanium nitride (TiN), nickel (Ni), tantalum (Ta), ruthenium (Ru), a conductive oxide (e.g., indium oxide (InO), indium tin oxide (InSnO), etc.), and/or the like. In some embodiments, the lower conductive fill 204C and the lower source/drain liner 204L may respectively have a thickness that is in a range of between approximately 1 nm and approximately 50 nm, between approximately 10 nm and approximately 50 nm, or other similar values.

A plurality of gate structures 106 are arranged within the ILD structure 202 above the plurality of lower source/drain contacts 204. The plurality of gate structures 106 are arranged along opposing sides of the plurality of lower source/drain contacts 204. The plurality of gate structures 106 include a gate electrode 108 and a gate dielectric 110 extending along outer surfaces of the gate electrode 108. In some embodiments, the gate dielectric 110 may extend along sidewalls and a lower surface of the gate electrode 108. In some embodiments, the gate electrode 108 may comprise one or more of molybdenum (Mo), titanium (Ti), tungsten (W), tantalum nitride (TaN), titanium nitride (TiN), nickel (Ni), tantalum (Ta), ruthenium (Ru), and/or the like. In some embodiments, the gate electrode 108 may have a thickness that is in a range of between approximately 1 nm and approximately 50 nm, between approximately 20 nm and approximately 50 nm, or other similar values. In some embodiments, the gate dielectric 110 may comprise a high-k dielectric material (e.g., a material having a dielectric constant that is greater than approximately 3.9). In some embodiments, the gate dielectric 110 may comprise one or more of aluminum oxynitride (AlON), aluminum nitride (AlN), aluminum oxide (AlO), Hafnium oxide (HfO₂), Hafnium zirconium oxide (HZO), zirconium oxide (ZrO₂), indium zirconium oxide (InZrO), titanium oxide (TiOx), titanium aluminum oxide (TiAlO), tantalum oxide (Ta2O5), Hafnium titanium oxide (HfTiO), Hafnium lanthanum oxide (HfLaO), and/or the like. In some embodiments, the gate dielectric 110 may have a thickness that is in a range of between approximately 1 nm and approximately 15 nm, between approximately 5 nm and approximately 10 nm, or other similar values.

A plurality of channels 112 are arranged vertically above the plurality of lower source/drain contacts 204 and laterally between neighboring ones of the plurality of gate structures 106. In some embodiments, the channel 112 may be entirely confined over the central upper surface 205c of the plurality of lower source/drain contacts. The plurality of channels 112 respectively comprise a channel material 114 and an insulating core of a channel insulating material 304. The channel material 114 laterally surrounds the channel insulating material 304, so as to separate the channel insulating material 304 from the plurality of gate structures 106. In some embodiments, the channel material 114 may comprise one or more of indium gallium zinc (InₓGa_{y}Zn_{z}O) (0≤x, y, z≤1), InₓGa_{y}Zn_{z}MO (wherein M can be Ti, Al, Ag, W, Ce, Sn, and/or the like), indium gallium oxide (IGO), indium zinc oxide (IZO), indium tungsten oxide (IWO), one or more tin doped oxide semiconductor materials, and/or the like. In some embodiments, the channel insulating material 304 may comprise one or more of an oxide semiconductor, aluminum oxide (AlOx), silicon dioxide (SiO2), silicon oxynitride (SiON), silicon carbide (SiC), silicon nitride (SiN), silicon carbon nitride (SiCN), gallium oxide (GaO), hafnium oxide (HfO₂), tantalum oxide (Ta₂O₅), titanium oxide (TiOₓ), zirconium oxide (ZrO₂), and/or other non-conductive materials.

In some embodiments, the plurality of channels 112 may respectively have a height that is in a range of between approximately 10 nm and approximately 100 nm, between approximately 30 nm and approximately 80 nm, and/or other similar values. In some embodiments, the channel material 114 may have a smaller height than the gate dielectric 110. In some embodiments, the channel material 114 may have a thickness that is in a range of between approximately 1 nm and approximately 10 nm, between approximately 5 nm and approximately 10 nm, or other similar values. In some embodiments, the thickness of the channel material 114 may vary over a height of the channel material 114. For example, the thickness of the channel material 114 may decrease as a height of the channel material 114 increases. In some embodiments, the channel insulating material 304 may have a thickness that is in a range of between approximately 5 nm and approximately 20 nm, between approximately 5 nm and approximately 25 nm, or other similar values. In some embodiments, the thickness of the channel insulating material 304 may also vary over a height of the channel insulating material 304. For example, the thickness of the channel insulating material 304 may decrease as a height of the channel insulating material 304 increases.

A plurality of upper source/drain contacts 206 are disposed within the ILD structure 202 above the plurality of channels 112 and the plurality of gate structures 106. In some embodiments, the plurality of upper source/drain contacts 206 may comprise an upper source/drain liner 206L and an upper conductive fill 206C disposed over the upper source/drain liner 206L. In some embodiments, the upper source/drain liner 206L may comprise one or more of Mo, Ti, W, TaN, TiN, Ni, Ta, Ru, a conductive oxide (e.g., InO, InSnO, etc.), and/or the like. In some embodiments, the upper conductive fill 206C may comprise one or more of Mo, Ti, TaN, TiN, W, Al, Cr, Ni, Ta, Ru, Co, Cu, and/or the like. In some embodiments, the upper source/drain liner 206L and the upper conductive fill 206C may respectively have a thickness that is in a range of between approximately 1 nm and approximately 50 nm, between approximately 10 nm and approximately 50 nm, or other similar values.

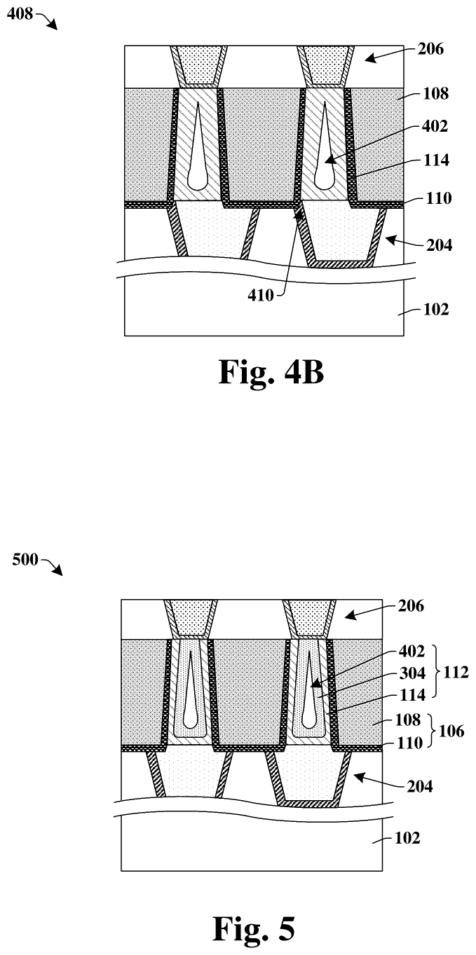

FIG. 4A illustrates some additional embodiments of an integrated chip structure 400 having a vertical transistor with a channel comprising a channel material surrounding an insulating core including an air-gap.

The integrated chip structure 400 comprises an ILD structure 202 disposed over a substrate 102. The ILD structure 202 includes a plurality of ILD layers 202a-202b stacked onto one another. For example, the ILD structure 202 may comprise a first ILD layer 202a and a second ILD layer 202b stacked onto the first ILD layer 202a. A plurality of lower source/drain contacts 204 are disposed within the first ILD layer 202a. A plurality of gate structures 106 are arranged within the ILD structure 202 above the plurality of lower source/drain contacts 204 and the first ILD layer 202a. The plurality of gate structures 106 are arranged along opposing sides of the plurality of lower source/drain contacts 204. The plurality of gate structures 106 include a gate electrode 108 and a gate dielectric 110 extending along outer surfaces of the gate electrode 108. A plurality of channels 112 are arranged vertically above the plurality of lower source/drain contacts 204 and laterally between neighboring ones of the plurality of gate structures 106. A plurality of upper source/drain contacts 206 are disposed within the ILD structure 202 above the plurality of channels 112 and the plurality of gate structures 106.

The plurality of channels 112 comprise a channel material 114 arranged along sidewalls of the plurality of gate structures 106. The channel material 114 has one or more internal surfaces that form an insulating core comprising an air-gap 402 within the plurality of channels 112. For example, the channel material 114 may comprise interior sidewalls that are spaced apart from one another by a space that forms the air-gap 402 directly over the plurality of lower source/drain contacts 204. The air-gap 402 is laterally separated by the channel material 114 from the plurality of gate structures 106. In some embodiments, the channel material 114 continuously extends between neighboring ones of the plurality of gate structures 106 at a first height over the substrate 102 and is discontinuous between the neighboring ones of the plurality of gate structures 106 at a second height over the substrate 102 that is less than the first height. In some embodiments, the channel material 114 continuously extends over a first width at a first height over the lower source/drain contacts 204 and the channel material 114 continuously extends over a second width at a second height over the lower source/drain contacts 204. In such embodiments, the first height is smaller than the second height and the first width is smaller than the second width. In some embodiments, the air-gap 402 may comprise one or more gases including one or more of oxygen, hydrogen, fluorinated gases (e.g., perfluorocarbons), hydrocarbon gases, and/or the like.

In some embodiments, the channel material 114 may have a first maximum height 404 and the air-gap 402 may have a second maximum height 406 that is less than the first maximum height 404. In some embodiments, a ratio of the second maximum height 406 to the first maximum height 404 may be between approximately 0.001 and approximately 0.9, between approximately 0.1 and approximately 0.9, between approximately 0.5 and approximately 0.9, or other similar values.

It will be appreciated that in different embodiments, the disclosed air-gaps may have different sizes and/or shapes. For example, in some embodiments shown in FIG. 4A, the air-gap 402 may comprise a tapered shape that vertically extends from between sidewalls of the channel material 114 to the plurality of lower source/drain contacts 204. In such embodiments, the air-gap 402 may be formed by sidewalls of the channel material 114 and an upper surface of the plurality of lower source/drain contacts 204. By having the air-gap 402 extend to the plurality of lower source/drain contacts 204, a capacitance of the integrated chip structure 400 may be further reduced over other shapes of air-gaps. In other embodiments, shown in cross-sectional view 408 of FIG. 4B, the air-gap 402 may comprise a tear drop shape formed by sidewalls and an upper surface of the channel material 114. In such embodiments, the air-gap 402 is completely surrounded by the channel material 114. Having the air-gap 402 completely surrounded by the channel material 114 may allow for simpler fabrication of the air-gap 402.

In some embodiments, shown in cross-sectional view 408 of FIG. 4B, the lower source/drain liner 204L may also comprise one or more protrusions 410 formed by a sidewall of the lower source/drain liner 204L that extends along a side of the plurality of gate structures 106 and directly between the plurality of gate structures 106 and the plurality of channels 112. In some embodiments, the sidewall extends outward from an upper surface of the lower source/drain liner 204L.

FIG. 5 illustrates some additional embodiments of an integrated chip structure 500 having a vertical transistor with a channel comprising a channel material surrounding an insulating core including a channel insulating material and an air-gap.

The integrated chip structure 500 comprises an ILD structure 202 disposed over a substrate 102. A plurality of lower source/drain contacts 204 are disposed within the ILD structure 202. A plurality of gate structures 106 are arranged within the ILD structure 202 above the plurality of lower source/drain contacts 204. The plurality of gate structures 106 are arranged along opposing sides of the plurality of lower source/drain contacts 204. The plurality of gate structures 106 include a gate electrode 108 and a gate dielectric 110 extending along outer surfaces of the gate electrode 108. A plurality of channels 112 are arranged vertically above the plurality of lower source/drain contacts 204 and laterally between neighboring ones of the plurality of gate structures 106. A plurality of upper source/drain contacts 206 are disposed within the ILD structure 202 above the plurality of channels 112 and the plurality of gate structures 106.

The plurality of channels 112 comprise a channel material 114 arranged along sidewalls of the plurality of gate structures 106. The channel material 114 surrounds an insulating core comprising a channel insulating material 304 and an air-gap 402. The channel insulating material 304 is arranged along one or more interior surfaces (e.g., interior sidewalls) of the channel material 114. In some embodiments, the channel insulating material 304 completely covers the interior sidewalls of the channel material 114. The channel insulating material 304 has one or more internal surfaces that form the air-gap 402 within the plurality of channels 112. The air-gap 402 is laterally separated by the channel material 114 and the channel insulating material 304 from the plurality of gate structures 106.

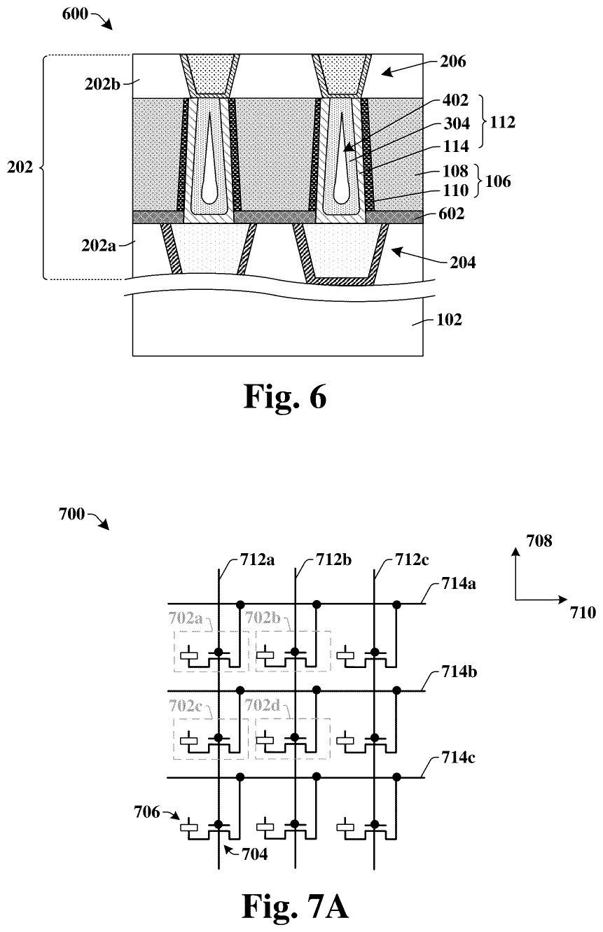

FIG. 6 illustrates some additional embodiments of an integrated chip structure 600 having a vertical transistor with a channel comprising a channel material surrounding an insulating core.

The integrated chip structure 600 comprises an ILD structure 202 disposed over a substrate 102. The ILD structure 202 includes a plurality of ILD layers 202a-202b stacked onto one another. For example, the ILD structure 202 may comprise a first ILD layer 202a and a second ILD layer 202b stacked onto the first ILD layer 202a. A plurality of lower source/drain contacts 204 are disposed within the first ILD layer 202a. A dielectric layer 602 is arranged over the first ILD layer 202a and the plurality of lower source/drain contacts 204. In various embodiments, the dielectric layer 602 may comprise an oxide (e.g., silicon dioxide), a nitride (e.g., silicon nitride, silicon oxynitride, etc.), a carbide (e.g., silicon carbide, silicon oxycarbide, etc.), and/or the like. In some embodiments, the dielectric layer 602 may extend over parts of the plurality of lower source/drain contacts 204.

A plurality of gate structures 106 are arranged above the dielectric layer 602. In some embodiments, the dielectric layer 602 vertically separates the plurality of gate structures 106 from the plurality of lower source/drain contacts 204. The plurality of gate structures 106 include a gate electrode 108 and a gate dielectric 110 extending along outer sidewalls of the gate electrode 108. A plurality of channels 112 are arranged vertically above the plurality of lower source/drain contacts 204 and laterally between neighboring ones of the plurality of gate structures 106. The plurality of channels 112 vertically extend through the dielectric layer 602 to the plurality of lower source/drain contacts 204. A plurality of upper source/drain contacts 206 are disposed within the ILD structure 202 above the plurality of channels 112 and the plurality of gate structures 106.

The plurality of channels 112 comprise a channel material 114 arranged along sidewalls of the plurality of gate structures 106. The channel material 114 surrounds an insulating core comprising a channel insulating material 304 and an air-gap 402. The channel insulating material 304 is arranged along one or more interior surfaces (e.g., interior sidewalls) of the channel material 114. In some embodiments, the channel insulating material 304 completely covers the one or more interior surfaces (e.g., interior sidewalls) of the channel material 114. The channel insulating material 304 has one or more internal surfaces that form an air-gap 402 within the plurality of channels 112. The air-gap 402 is laterally separated by the channel material 114 and the channel insulating material 304 from the plurality of gate structures 106.

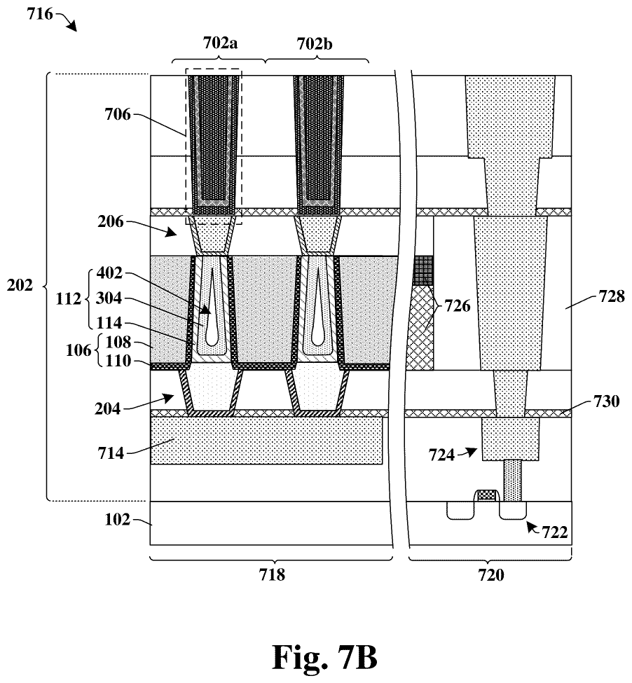

FIGS. 7A-7B illustrate some embodiments of an integrated chip memory structure having a vertical transistor with a channel comprising a channel material surrounding an insulating core.

FIG. 7A illustrates a schematic diagram 700 of some embodiments of the disclosed integrated chip memory structure.

As shown in the schematic diagram 700, the integrated chip structure comprises a memory array including a plurality of memory cells 702a-702d arranged within columns (extending along a first direction 708) and rows (extending along a second direction 710). The plurality of memory cells 702a-702d respectively comprise an access transistor 704 and a data storage element 706. The access transistor 704 is configured to control access to the data storage element 706. The access transistor 704 comprises a gate electrode coupled to a plurality of word-lines 712a-712c. The access transistor 704 further comprises a source/drain region coupled to a plurality of bit-lines 714a-714c.

The plurality of word-lines 712a-712c and the plurality of bit-lines 714a-714c may be further coupled to control circuitry (e.g., a sense amplifier, decoder, etc.) configured to selectively control access to the plurality of memory cells 702a-702d. For example, in some embodiments a write operation may be performed on a first memory cell 702a by applying a positive write voltage to a first word-line 712a and a first bit-line 714a. In some embodiments, a read operation may be performed on the first memory cell by applying a read voltage (e.g., having a voltage that is less than the positive write voltage) to the first word-line 712a.

FIG. 7B illustrates a cross-sectional view 716 showing some embodiments of a disclosed integrated chip memory structure corresponding to a section of the schematic diagram 700 of FIG. 7A.

As shown in cross-sectional view 716, the integrated chip memory structure comprises an embedded memory region 718 and a logic region 720. The embedded memory region 718 includes a plurality of memory cells 702a-702b. The integrated chip memory structure comprises an ILD structure 202 disposed over a substrate 102. In some embodiments, the ILD structure 202 comprises a plurality of ILD layers stacked onto one another. In some embodiments, adjacent ones of the ILD layers may be separated from one another by etch stop layers 730.

The embedded memory region 718 comprises a plurality of gate structures 106 arranged within the ILD structure 202 between a plurality of lower source/drain contacts 204 and a plurality of upper source/drain contacts 206. In some embodiments, the plurality of lower source/drain contacts may be coupled to a bit-line 714. The plurality of gate structures 106 include a gate electrode 108 and a gate dielectric 110 extending along outer surfaces of the gate electrode 108. A plurality of channels 112 are arranged vertically above the plurality of lower source/drain contacts 204 and laterally between neighboring ones of the plurality of gate structures 106. The plurality of channels 112 comprise a channel material 114 arranged along sidewalls of the plurality of gate structures 106 and a channel insulating material 304 arranged along interior surfaces of the channel material 114. The channel insulating material 304 has one or more internal surfaces that form an air-gap 402 within the plurality of channels 112.

The plurality of upper source/drain contacts 206 are coupled to a data storage element 706 configured to store a first data state (e.g., a logical ‘0’) or a second a second data state (e.g., a logical ‘1’). In some embodiments, the data storage element 706 may comprise a capacitor. In other embodiments, the data storage element 706 may comprise a resistive random access memory device (RRAM), a ferroelectric random access memory (FeRAM) device, a magneto resistive random access memory (MRAM) device, a phase change random access memory (PCRAM) device, and/or the like.

The logic region 720 comprises a logic device 722 (e.g., a field effect transistor (FET), a FinFET, a gate all around transistor, a nanosheet transistor, and/or the like). The logic device 722 is coupled to a plurality of overlying interconnects 724. In some embodiments, an edge of the memory array may comprise one or more sacrificial materials 726 laterally abutting an ILD layer 728 surrounding one or more of the interconnects 724. The one or more sacrificial materials 726 may comprise one or more of silicon dioxide (SiO₂), silicon oxynitride (SiON), silicon nitride (SiN), silicon carbon nitride (SiCN), titanium oxide (TiOx), amorphous silicon (a-Si), amorphous carbon (a-C), and/or other low-k dielectrics

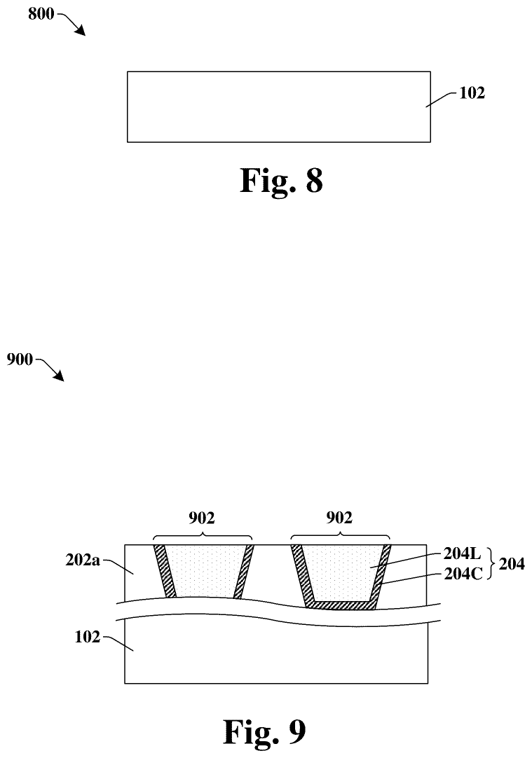

FIGS. 8-17 illustrate cross-sectional views 800-1700 of some embodiments of a method of forming an integrated chip structure having a vertical transistor with a channel comprising a channel material surrounding an insulating core including a channel insulating material. Although the embodiments shown in FIGS. 8-17 are described with reference to a method, it will be appreciated that the structures shown in FIGS. 8-17 are not limited to the method of formation but rather may stand alone separate of the method.

As shown in cross-sectional view 800 of FIG. 8, a substrate 102 is provided. In various embodiments, the substrate 102 may comprise and/or be any type of semiconductor body (e.g., silicon/CMOS bulk, SiGe, SOI, etc.) such as a semiconductor wafer or one or more die on a wafer, as well as any other type of semiconductor and/or epitaxial layers formed thereon and/or otherwise associated therewith.

As shown in cross-sectional view 900 of FIG. 9, a first inter-level dielectric (ILD) layer 202a is formed over the substrate 102. In some embodiments, the first ILD layer 202a may be formed by one or more deposition processes (e.g., a physical vapor deposition (PVD) process, a chemical vapor deposition (CVD) process, a plasma enhanced CVD (PE-CVD) process, an atomic layer deposition (ALD) process, a plasma enhanced ALD (PE-ALD) process, a thermal ALD process, a spin-on process, a metal doping process, a metal oxidation process, a sputtering process, and/or the like). In some embodiments, the first ILD layer 202a may comprise silicon dioxide, silicon oxynitride (SiN), silicon carbon nitride (SiCN), titanium oxide (TiOx), amorphous silicon (a-Si), amorphous carbon (a-C), carbon doped silicon oxide (SiCOH), phosphosilicate glass (PSG), borophosphosilicate glass (BPSG), borosilicate glass (BSG), fluorosilicate glass (FSG), undoped silicate glass (USG), and/or the like. In some embodiments (not shown), one or more additional ILD layers may be disposed between the first ILD layer 202a and the substrate 102.

A patterning process is performed on the first ILD layer 202a to form a plurality of lower source/drain openings 902 respectively formed by sidewalls of the first ILD layer 202a. In some embodiments, the patterning process may comprise a lithography process followed by an etching process that selectively exposes the first ILD layer 202a to an etchant. In various embodiments, the etchant may comprise a dry etchant having an etching chemistry comprising a fluorine species (e.g., CF₄, CHF₃, C₄F₈, etc.) or a wet etchant comprising hydrofluoric acid (HF), potassium hydroxide (KOH), or the like.

A plurality of lower source/drain contacts 204 are formed within the plurality of lower source/drain openings 902. In some embodiments, the plurality of lower source/drain contacts 204 may be formed by forming a lower source/drain liner 204L within the plurality of lower source/drain openings 902 and over the first ILD layer 202a. In some embodiments, the lower source/drain liner 204L may comprise one or more of molybdenum (Mo), titanium (Ti), tantalum nitride (TaN), titanium nitride (TiN), tungsten (W), aluminum (Al), chromium (Cr), nickel (Ni), tantalum (Ta), ruthenium (Ru), cobalt (Co), copper (Cu), and/or the like. A lower conductive fill 204C is subsequently formed over the lower source/drain liner 204L. In some embodiments, the lower conductive fill 204C may comprise one or more of molybdenum (Mo), titanium (Ti), tungsten (W), tantalum nitride (TaN), titanium nitride (TiN), nickel (Ni), tantalum (Ta), ruthenium (Ru), a conductive oxide (e.g., InO, InSnO, etc.), and/or the like. In some embodiments, the lower source/drain liner 204L and the lower conductive fill 204C may be formed by one or more deposition processes (e.g., a PVD process, a CVD process, a PE-CVD process, an ALD process, a PE-ALD process, a thermal ALD process, a spin-on process, a metal doping process, a metal oxidation process, a sputtering process, and/or the like). After forming the lower source/drain liner 204L and the lower conductive fill 204C, a planarization process (e.g., a chemical mechanical planarization (CMP) process) may be performed to remove parts of the lower source/drain liner 204L and the lower conductive fill 204C that are over the first ILD layer 202a.

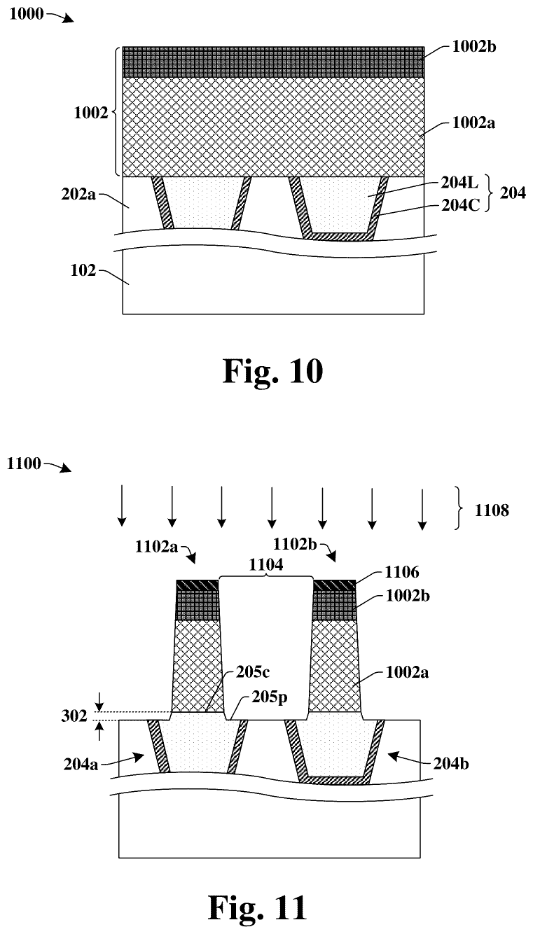

As shown in cross-sectional view 1000 of FIG. 10, a sacrificial structure 1002 is formed over the first ILD layer 202a and the lower source/drain contacts 204. In some embodiments, the sacrificial structure 1002 may comprise a first sacrificial material 1002a and a second sacrificial material 1002b stacked onto the first sacrificial material 1002a. In some embodiments, the first sacrificial material 1002a and the second sacrificial material 1002b may comprise one or more of silicon dioxide (SiO₂), silicon oxynitride (SiON), silicon nitride (SiN), silicon carbon nitride (SiCN), titanium oxide (TiOx), amorphous silicon (a-Si), amorphous carbon (a-C), and/or other low-k dielectrics. The sacrificial structure 1002 may be formed by one or more deposition processes (e.g., a PVD process, a CVD process, a PE-CVD process, a sputtering process, an ALD process, a PE-ALD process, a spin-on process, and/or the like). In some embodiments, the sacrificial structure 1002 may have a thickness that is in a range of between approximately 1 nm and approximately 150 nm, between approximately 50 nm and approximately 150 nm, or other similar values.

As shown in cross-sectional view 1100 of FIG. 11, the sacrificial structure (e.g., 1002 of FIG. 10) is selectively patterned to form a plurality of sacrificial pillars 1102a-1102b over the plurality of lower source/drain contacts 204a-204b. For example, a first sacrificial pillar 1102a is formed over a first lower source/drain contact 204a, a second sacrificial pillar 1102b is formed over a second lower source/drain contact 204b, etc. The plurality of sacrificial pillars 1102a-1102b are laterally separated from one another by gate structure openings 1104. In some embodiments, the plurality of sacrificial pillars 1102a-1102b respectively comprise the first sacrificial material 1002a and the second sacrificial material 1002b. In some embodiments, parts of the lower source/drain contacts 204a-204b may also be removed, so that the lower source/drain contacts 204a-204b respectively comprise a central upper surface 205c and a peripheral upper surface 205p that is vertically below and laterally surrounding the central upper surface 205c. The plurality of sacrificial pillars 1102a-1102b are disposed above the central upper surface 205c.

In some embodiments, the sacrificial structure may be patterned according to a pattern process that includes a lithography process that forms a mask 1106 over the sacrificial structure followed by an etching process that selectively exposes the sacrificial structure to an etchant 1108 according to the mask 1106. In various embodiments, the etchant 1108 may comprise a dry etchant having an etching chemistry comprising a fluorine species (e.g., CF₄, CHF₃, C₄F₈, etc.) or a wet etchant comprising hydrofluoric acid (HF), potassium hydroxide (KOH), or the like

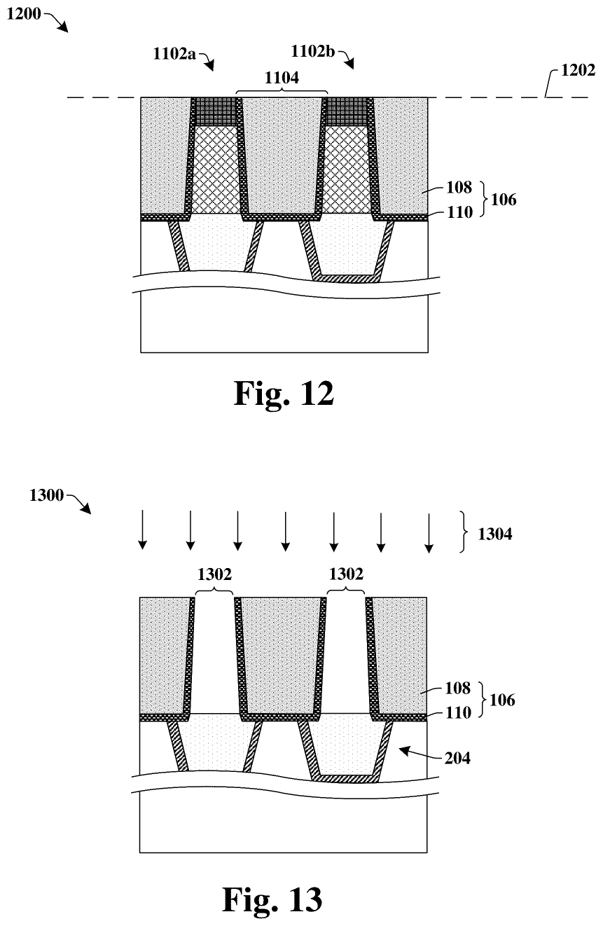

As shown in cross-sectional view 1200 of FIG. 12, a plurality of gate structures 106 are formed within the gate structure openings 1104 and on opposing sides of the plurality of sacrificial pillars 1102a-1102b. The plurality of gate structures 106 may be formed by depositing a gate dielectric 110 within the gate structure openings 1104 and over the plurality of sacrificial pillars 1102a-1102b. A gate electrode 108 may be subsequently deposited within the gate structure openings 1104 and over the gate dielectric 110. After forming the gate electrode 108, a planarization process 1202 (e.g., a CMP process) may be performed to remove parts of the gate dielectric 110 and the gate electrode 108 that are over the plurality of sacrificial pillars 1102a-1102b. The planarization process 1202 forms the plurality of gate structures 106.

In some embodiments, the gate dielectric 110 may comprise a high-k dielectric material. In some embodiments, the gate dielectric 110 may comprise one or more of aluminum oxynitride (AlON), aluminum nitride (AlN), aluminum oxide (AlO), Hafnium oxide (HfO₂), Hafnium zirconium oxide (HZO), zirconium oxide (ZrO₂), indium zirconium oxide (InZrO), titanium oxide (TiOx), titanium aluminum oxide (TiAlO), tantalum oxide (Ta2O5), Hafnium titanium oxide (HfTiO), Hafnium lanthanum oxide (HfLaO), and/or the like. In some embodiments, the gate electrode 108 may comprise one or more of molybdenum (Mo), titanium (Ti), tungsten (W), tantalum nitride (TaN), titanium nitride (TiN), nickel (Ni), tantalum (Ta), ruthenium (Ru), and/or the like. In some embodiments, the gate dielectric 110 and the gate electrode 108 may be formed by one or more deposition processes (e.g., a PVD process, a CVD process, a PE-CVD process, an ALD process, a PE-ALD process, a thermal ALD process, a spin-on process, a metal doping process, a metal oxidation process, a sputtering process, and/or the like).

As shown in cross-sectional view 1300 of FIG. 13, the plurality of sacrificial pillars (e.g., 1102a-1102b of FIG. 12) are removed from between neighboring ones of the plurality of gate structures 106. Removal of the plurality of sacrificial pillars forms a plurality of channel openings 1302 between the plurality of gate structures 106. The plurality of channel openings 1302 expose the lower source/drain contacts 204. In some embodiments, the plurality of sacrificial pillars may be removed by exposing the plurality of sacrificial pillars to an etchant 1304.

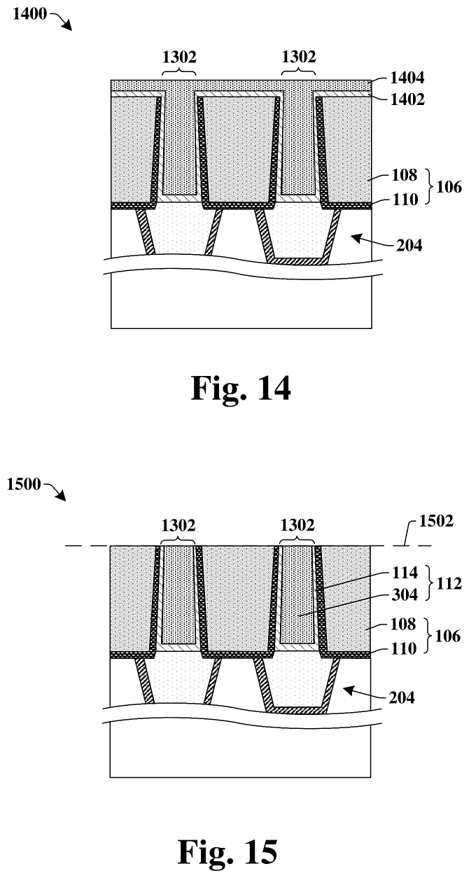

As shown in cross-sectional view 1400 of FIG. 14, a channel material layer 1402 is formed within the channel openings 1302 and lining sidewalls and upper surfaces of the plurality of gate structures 106. The channel material layer 1402 comprises one or more interior surfaces that are spaced apart from one another by a space directly over the lower source/drain contacts 204. A channel insulating material layer 1404 is subsequently formed within the channel openings 1302 and lining sidewalls and upper surfaces of the channel material layer 1402. In some embodiments, the channel material layer 1402 may comprise one or more of indium gallium zinc (InₓGa_{y}Zn_{z}O) (0≤x, y, z≤1), InₓGa_{y}Zn_{z}MO (wherein M can be Ti, Al, Ag, W, Ce, Sn, and/or the like), indium gallium oxide (IGO), indium zinc oxide (IZO), indium tungsten oxide (IWO), tin doped oxide semiconductor materials, and/or the like. In some embodiments, the channel insulating material layer 1404 may comprise one or more of aluminum oxide (AlOx), silicon dioxide (SiO2), silicon oxynitride (SiON), silicon carbide (SiC), silicon nitride (SiN), silicon carbon nitride (SiCN), gallium oxide (GaO), hafnium oxide (HfO₂), tantalum oxide (Ta₂O₅), titanium oxide (TiOₓ), zirconium oxide (ZrO₂), and/or other non-conductive materials. In some embodiments, the channel material layer 1402 and/or the channel insulating material layer 1404 may be formed by one or more deposition processes (e.g., a PVD process, a CVD process, a PE-CVD process, an ALD process, a PE-ALD process, a thermal ALD process, a spin-on process, a metal doping process, a metal oxidation process, a sputtering process, and/or the like).

As shown in cross-sectional view 1500 of FIG. 15, a planarization process 1502 (e.g., a chemical mechanical planarization process) may be performed to remove parts of channel material layer (e.g., 1402 of FIG. 14) and the channel insulating material layer (e.g., 1404 of FIG. 14) that are over the plurality of gate structures 106. The planarization process 1502 forms a plurality of channels 112 within the channel openings 1302. The plurality of channels 112 respectively comprise a channel material 114 having interior sidewalls facing towards opposing sides of an insulating core comprising a channel insulating material 304 disposed over the lower source/drain contact 204.

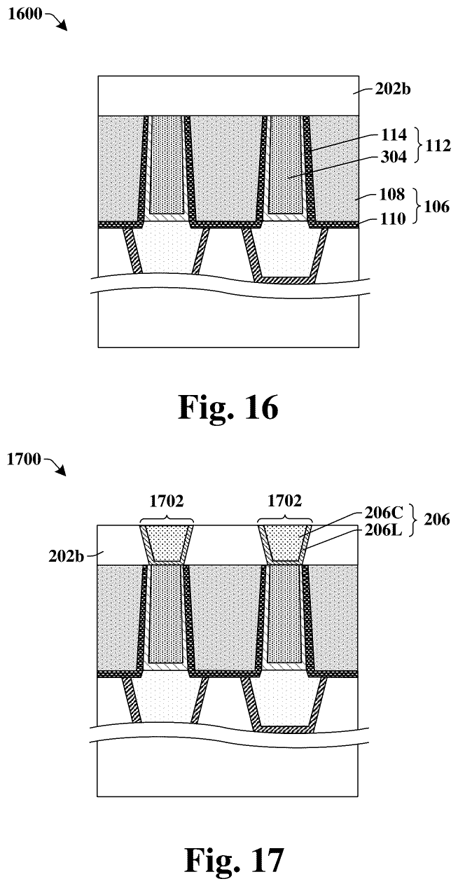

As shown in cross-sectional view 1600 of FIG. 16, a second ILD layer 202b is formed over the plurality of gate structures 106, the channel material 114, and the channel insulating material 304. In some embodiments, the second ILD layer 202b may be formed by one or more deposition processes (e.g., a PVD process, a CVD process, a PE-CVD process, an ALD process, a PE-ALD process, a thermal ALD process, a spin-on process, a metal doping process, a metal oxidation process, a sputtering process, and/or the like). In some embodiments, the second ILD layer 202b may comprise one or more of silicon dioxide, SiON, SiN, SiCN, TiOx, a-Si, a-C, SiCOH, PSG, BPSG, BSG, FSG, USG, and/or the like.

As shown in cross-sectional view 1700 of FIG. 17, a patterning process is performed on the second ILD layer 202b to form a plurality of upper source/drain openings 1702 respectively formed by sidewalls of the second ILD layer 202b. A plurality of upper source/drain contacts 206 are formed within the plurality of upper source/drain openings 1702. In some embodiments, the plurality of upper source/drain contacts 206 may be formed by forming an upper source/drain liner 206L within the plurality of upper source/drain openings 1702 and over the second ILD layer 202b. In some embodiments, the upper source/drain liner 206L may comprise one or more of Mo, Ti, W, TaN, TiN, Ni, Ta, Ru, a conductive oxide (e.g., InO, InSnO, etc.), and/or the like. An upper conductive fill 206C is subsequently formed over the upper source/drain liner 206L. In some embodiments, the upper conductive fill 206C may comprise one or more of Mo, Ti, TaN, TiN, W, Al, Cr, Ni, Ta, Ru, Co, Cu, and/or the like. In some embodiments, the upper source/drain liner 206L and the upper conductive fill 206C may be formed by one or more deposition processes (e.g., a PVD process, a CVD process, a PE-CVD process, an ALD process, a PE-ALD process, a thermal ALD process, a spin-on process, a metal doping process, a metal oxidation process, a sputtering process, and/or the like). After forming the upper source/drain liner 206L and the upper conductive fill 206C, a planarization process (e.g., a CMP process) may be performed to remove parts of the upper source/drain liner 206L and the upper conductive fill 206C that are over the second ILD layer 202b.

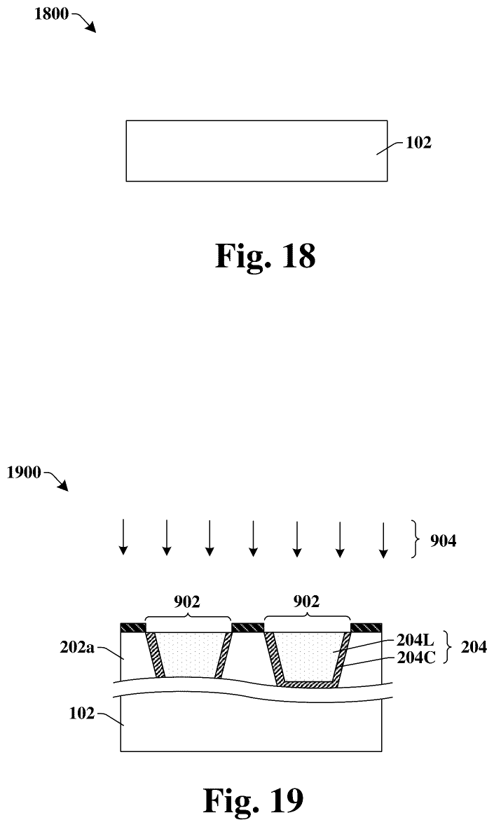

FIGS. 18-27 illustrate cross-sectional views of some additional embodiments of a method of forming an integrated chip structure having a vertical transistor with a channel comprising a channel material surrounding an insulating core including an air-gap. Although the embodiments shown in FIGS. 18-27 are described with reference to a method, it will be appreciated that the structures shown in FIGS. 18-27 are not limited to the method of formation but rather may stand alone separate of the method.

As shown in cross-sectional view 1800 of FIG. 18, a substrate 102 is provided. In various embodiments, the substrate 102 may comprise and/or be any type of semiconductor body (e.g., silicon/CMOS bulk, SiGe, SOI, etc.) such as a semiconductor wafer or one or more die on a wafer, as well as any other type of semiconductor and/or epitaxial layers formed thereon and/or otherwise associated therewith.

As shown in cross-sectional view 1900 of FIG. 19, a first ILD layer 202a is formed over the substrate 102. A patterning process is performed on the first ILD layer 202a to form a plurality of lower source/drain openings 902 respectively formed by sidewalls of the first ILD layer 202a. In some embodiments, the patterning process may comprise a lithography process followed by an etching process that selectively exposes the first ILD layer 202a to an etchant 904. A plurality of lower source/drain contacts 204 are formed within the plurality of lower source/drain openings 902. In some embodiments, the plurality of lower source/drain contacts 204 may be formed by forming a lower source/drain liner 204L within the plurality of lower source/drain openings 902 and over the first ILD layer 202a. A lower conductive fill 204C is subsequently formed over the lower source/drain liner 204L. After forming the lower source/drain liner 204L and the lower conductive fill 204C, a planarization process (e.g., a CMP process) may be performed to remove parts of the lower source/drain liner 204L and the lower conductive fill 204C that are over the first ILD layer 202a.

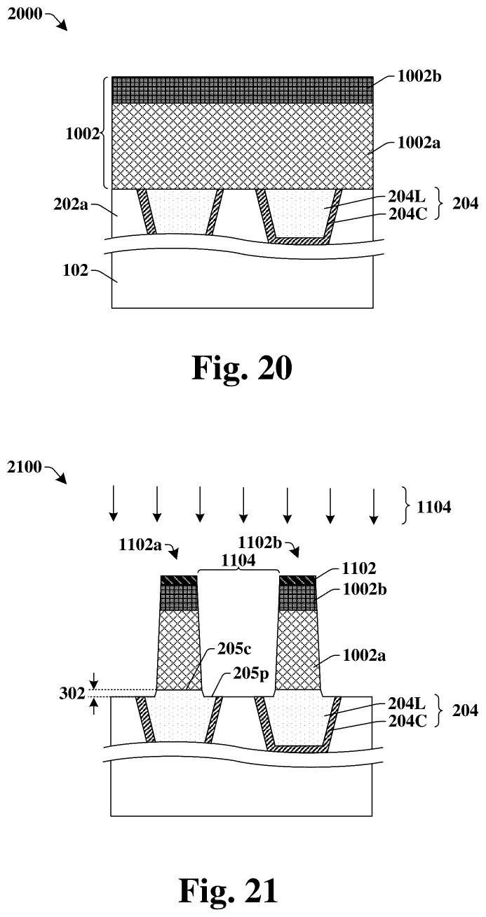

As shown in cross-sectional view 2000 of FIG. 20, a sacrificial structure 1002 is formed over the first ILD layer 202a and the lower source/drain contacts 204. In some embodiments, the sacrificial structure 1002 may comprise a first sacrificial material 1002a and a second sacrificial material 1002b stacked onto the first sacrificial material 1002a.

As shown in cross-sectional view 2100 of FIG. 21, the sacrificial structure (e.g., 1002 of FIG. 20) is selectively patterned to form a plurality of sacrificial pillars 1102a-1102b over the plurality of lower source/drain contacts 204. The plurality of sacrificial pillars 1102a-1102b are laterally separated from one another by gate structure openings 1104. In some embodiments, the plurality of sacrificial pillars 1102a-1102b respectively comprise the first sacrificial material 1002a and the second sacrificial material 1002b. In some embodiments, parts of the lower source/drain contacts 204a-204b may also be removed, so that the lower source/drain contacts 204 respectively comprise a central upper surface 205c and a peripheral upper surface 205p that is vertically below and laterally surrounding the central upper surface 205c.

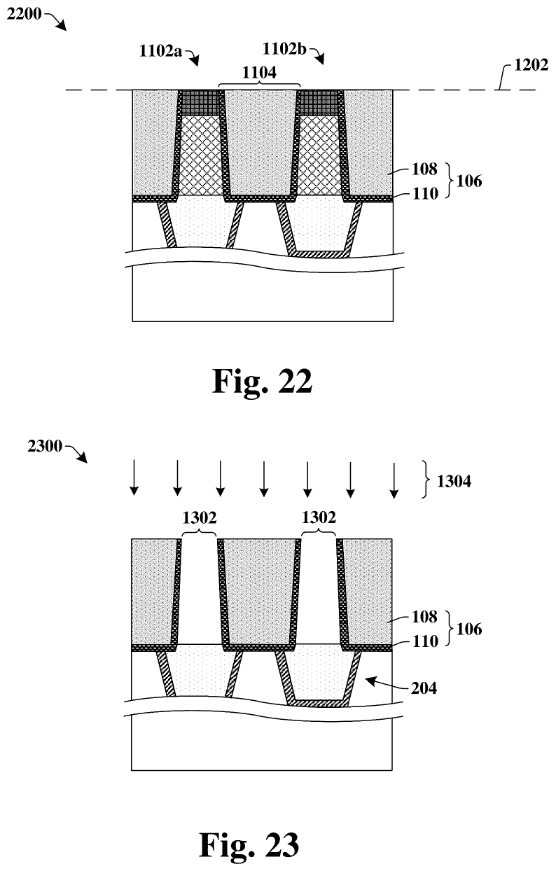

As shown in cross-sectional view 2200 of FIG. 22, a plurality of gate structures 106 are formed within the gate structure openings 1104 and on opposing sides of the plurality of sacrificial pillars 1102a-1102b. The plurality of gate structures 106 may be formed by depositing a gate dielectric 110 within the gate structure openings 1104 and over the plurality of sacrificial pillars 1102a-1102b. A gate electrode 108 may be subsequently deposited within the gate structure openings 1104 and over the gate dielectric 110. After forming the gate electrode 108, a planarization process 1202 (e.g., a CMP process) may be performed to remove parts of the gate dielectric 110 and the gate electrode 108 that are over the plurality of sacrificial pillars 1102a-1102b.

As shown in cross-sectional view 2300 of FIG. 23, the plurality of sacrificial pillars (e.g., 1102a-1102b of FIG. 22) are removed from between neighboring ones of the plurality of gate structures 106. Removal of the plurality of sacrificial pillars forms a plurality of channel openings 1302 between the plurality of gate structures 106.

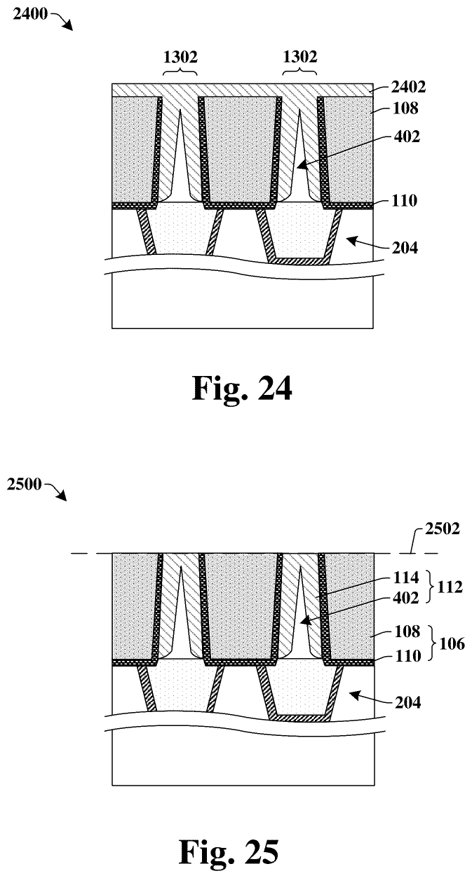

As shown in cross-sectional view 2400 of FIG. 24, a channel material layer 2402 is formed within the channel openings 1302 and lining sidewalls and upper surfaces of the plurality of gate structures 106. In some embodiments, the channel material layer 2402 may comprise one or more of InₓGa_{y}Zn_{z}O (0≤x, y, z≤1), InₓGa_{y}Zn_{z}MO (wherein M can be Ti, Al, Ag, W, Ce, Sn, and/or the like), IGO, IZO, IWO, tin doped oxide semiconductor materials, and/or the like. The channel material layer 1402 has interior sidewalls that face one another to form an air-gap 402 over the lower source/drain contact 204.

As shown in cross-sectional view 2500 of FIG. 25, a planarization process 2502 (e.g., a CMP process) may be performed to remove parts of channel material layer (e.g., 2402 of FIG. 24) that are over the plurality of gate structures 106. The planarization process 2502 forms a channel 112 comprising a channel material 114 having interior sidewalls facing towards opposing sides of the air-gap 402 disposed over the lower source/drain contacts 204.

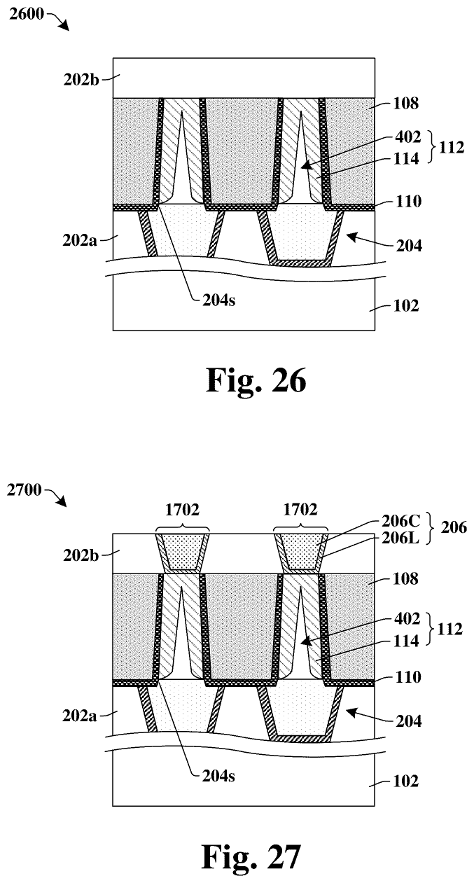

As shown in cross-sectional view 2600 of FIG. 26, a second ILD layer 202b is formed over the plurality of gate structures 106 and the channel 112. In some embodiments, the second ILD layer 202b may be formed by one or more deposition processes (e.g., a PVD process, a CVD process, a PE-CVD process, an ALD process, a sputtering process, and/or the like). In some embodiments, the second ILD layer 202b may comprise silicon dioxide, SiON, SiN, SiCN, TiOx, a-Si, a-C, SiCOH, PSG, BPSG, BSG, FSG, USG, and/or the like

As shown in cross-sectional view 2700 of FIG. 27, a patterning process is performed on the second ILD layer 202b to form a plurality of upper source/drain openings 1702 respectively formed by sidewalls of the second ILD layer 202b. A plurality of upper source/drain contacts 206 are formed within the plurality of upper source/drain openings 1702. In some embodiments, the plurality of upper source/drain contacts 206 may be formed by forming an upper source/drain liner 206L within the plurality of upper source/drain openings 1702 and over the second ILD layer 202b. An upper conductive fill 206C is subsequently formed over the upper source/drain liner 206L. After forming the upper source/drain liner 206L and the upper conductive fill 206C, a planarization process (e.g., a CMP process) may be performed to remove parts of the upper source/drain liner 206L and the upper conductive fill 206C that are over the second ILD layer 202b.

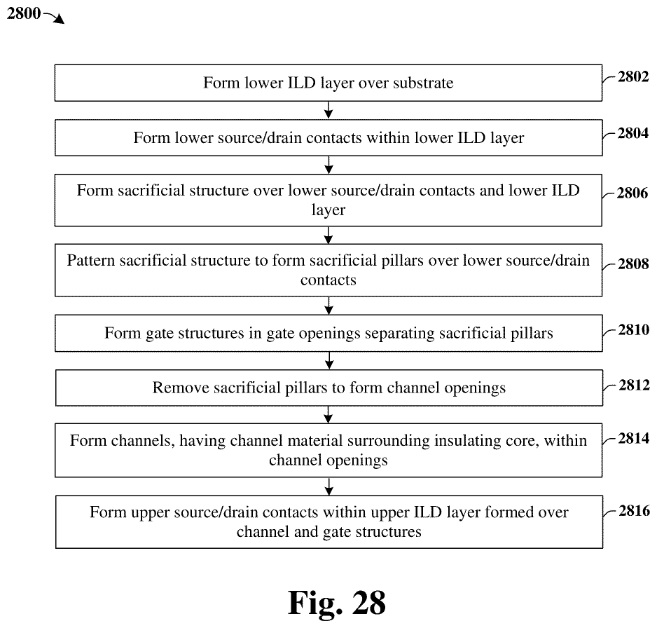

FIG. 28 illustrates a flow diagram of some embodiments of a method of forming an integrated chip structure having a vertical transistor with a channel comprising a channel material surrounding an insulating core.

While method 2800 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 2802, a lower inter-level dielectric (ILD) layer is formed over a substrate. FIG. 8 illustrates a cross-sectional view 800 of some embodiments corresponding to act 2802. FIG. 18 illustrates a cross-sectional view 1800 of some additional embodiments corresponding to act 2802.

At act 2804, a plurality of lower source/drain contacts are formed within the lower ILD layer. FIG. 9 illustrates a cross-sectional view 900 of some embodiments corresponding to act 2804. FIG. 19 illustrates a cross-sectional view 1900 of some additional embodiments corresponding to act 2804.

At act 2806, a sacrificial structure is formed over the lower source/drain contacts and the lower ILD layer. FIG. 10 illustrates a cross-sectional view 1000 of some embodiments corresponding to act 2806. FIG. 20 illustrates a cross-sectional view 2000 of some additional embodiments corresponding to act 2806.

At act 2808, the sacrificial structure is patterned to form a plurality of sacrificial pillars over the plurality of lower source/drain contacts. FIG. 11 illustrates a cross-sectional view 1100 of some embodiments corresponding to act 2808. FIG. 21 illustrates a cross-sectional view 2100 of some additional embodiments corresponding to act 2808.

At act 2810, a plurality of gate structures are formed within gate openings separating the plurality of sacrificial pillars. FIG. 12 illustrates a cross-sectional view 1200 of some embodiments corresponding to act 2810. FIG. 22 illustrates a cross-sectional view 2200 of some additional embodiments corresponding to act 2810.

At act 2812, the sacrificial pillars are removed to form channel openings between the plurality of gate structures. FIG. 13 illustrates a cross-sectional view 1300 of some embodiments corresponding to act 2812. FIG. 23 illustrates a cross-sectional view 2300 of some additional embodiments corresponding to act 2812.

At act 2814, a channel is formed within the channel openings. The channel comprises a channel material surrounding an insulating core. FIGS. 14-15 illustrate cross-sectional views 1400-1500 of some embodiments corresponding to act 2814. FIGS. 24-25 illustrate cross-sectional views 2400-2500 of some additional embodiments corresponding to act 2814.

At act 2816, a plurality of upper source/drain contacts are formed within an upper ILD layer formed over the channel and the plurality of gate structures. FIGS. 16-17 illustrate cross-sectional views 1600-1700 of some embodiments corresponding to act 2816. FIGS. 26-27 illustrate cross-sectional views 2600-2700 of some additional embodiments corresponding to act 2816.

Accordingly, in some embodiments, the present disclosure relates to an integrated chip structure having a vertical transistor having a channel with a channel material and an insulating core.

In some embodiments, the present disclosure relates to an integrated chip. The integrated chip includes a lower source/drain over a substrate; a channel arranged over the lower source/drain; an upper source/drain over the channel; gate electrodes arranged along opposing sides of the channel; and the channel including a channel material laterally surrounding an insulating core disposed over the lower source/drain, the channel material laterally separating the insulating core from the gate electrodes.

In other embodiments, the present disclosure relates to a method of forming an integrated chip. The method includes forming a lower source/drain contact within a lower inter-level dielectric (ILD) layer over a substrate; forming a sacrificial structure over the lower source/drain contact and the lower ILD layer; patterning the sacrificial structure to form a sacrificial pillar over the lower source/drain contact; forming gate structures over the lower ILD layer and along opposing sidewalls of the sacrificial pillar; removing the sacrificial pillar to form a channel opening between the gate structures and exposing the lower source/drain contact; and forming a channel within the channel opening, the channel including a channel material having interior sidewalls facing towards opposing sides of an insulating core.

In yet other embodiments, the present disclosure relates to a method of forming an integrated chip. The method includes forming a lower source/drain contact within a lower inter-level dielectric (ILD) layer over a substrate; forming a sacrificial pillar over the lower source/drain contact; forming gate structures over the lower ILD layer and along opposing sidewalls of the sacrificial pillar; removing the sacrificial pillar to form a channel opening between the gate structures; and forming a channel material within the channel opening and along sidewalls of the gate structures, the channel material including one or more interior surfaces that are spaced apart from one another by a space directly over the lower source/drain contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a lower source/drain over a substrate;
a channel arranged over the lower source/drain;
an upper source/drain over the channel;
gate electrodes arranged along opposing sides of the channel; and
wherein the channel comprises a channel material laterally surrounding an insulating core disposed over the lower source/drain, the channel material laterally separating the insulating core from the gate electrodes.

2. The integrated chip of claim 1, wherein the lower source/drain comprises a lower source/drain contact including a central upper surface and a peripheral upper surface that is vertically below and laterally surrounding the central upper surface, the channel being disposed above the central upper surface.

3. The integrated chip of claim 1, wherein the insulating core comprises a dielectric material laterally contacting the channel material.

4. The integrated chip of claim 1, wherein the insulating core comprises an air-gap including a gas.

5. The integrated chip of claim 1, further comprising:
a gate dielectric continuously extending along sidewalls and a lower surface of the gate electrodes.

6. The integrated chip of claim 5, wherein the gate dielectric has a first height and the channel material has a second height that is less than the first height.

7. The integrated chip of claim 1, wherein the channel material has a thickness that varies over a height of the channel material.

8. The integrated chip of claim 1, wherein the channel material continuously extends over a first width at a first height over the lower source/drain and wherein the channel material continuously extends over a second width at a second height over the lower source/drain, the first height being smaller than the second height and the first width being smaller than the second width.

9. The integrated chip of claim 1, wherein the channel material comprises an oxide semiconductor.

10. A method of forming an integrated chip, comprising:
forming a lower source/drain contact within a lower inter-level dielectric (ILD) layer over a substrate;
forming a sacrificial structure over the lower source/drain contact and the lower ILD layer;
patterning the sacrificial structure to form a sacrificial pillar over the lower source/drain contact;
forming gate structures over the lower ILD layer and along opposing sidewalls of the sacrificial pillar;
removing the sacrificial pillar to form a channel opening between the gate structures and exposing the lower source/drain contact; and
forming a channel within the channel opening, wherein the channel comprises a channel material having interior sidewalls facing towards opposing sides of an insulating core.

11. The method of claim 10, wherein the sacrificial structure comprises:
a first dielectric material; and
a second dielectric material disposed over the first dielectric material.

12. The method of claim 10, wherein forming the channel comprises:
depositing the channel material within the channel opening, wherein the channel material lines sidewalls and an upper surface of the gate structures; and
depositing a channel insulating material within the channel opening, wherein the channel insulating material lines the interior sidewalls and an upper surface of the channel material.

13. The method of claim 10, wherein forming the channel comprises:
depositing the channel material within the channel opening, wherein the channel material comprises one or more interior surfaces that form an air-gap directly over the lower source/drain contact.

14. The method of claim 10, wherein forming the gate structures comprises:
forming a gate dielectric along the opposing sidewalls and an upper surfaces of the sacrificial pillar; and
forming a gate electrode along sidewalls and over the gate dielectric.

15. The method of claim 10, wherein the lower source/drain contact has a bottommost surface with a first width, a topmost surface with a second width, and a third width vertically between the topmost surface and the bottommost surface, the third width being larger than the first width and the second width.

16. The method of claim 10, wherein the lower source/drain contact comprises a central upper surface and a peripheral upper surface surrounding the central upper surface, the channel being entirely confined over the central upper surface.

17. A method of forming an integrated chip, comprising:
forming a lower source/drain contact within a lower inter-level dielectric (ILD) layer over a substrate;
forming a sacrificial pillar over the lower source/drain contact;
forming gate structures over the lower ILD layer and along opposing sidewalls of the sacrificial pillar;
removing the sacrificial pillar to form a channel opening between the gate structures; and
forming a channel material within the channel opening and along sidewalls of the gate structures, wherein the channel material comprises one or more interior surfaces that are spaced apart from one another by a space directly over the lower source/drain contact.

18. The method of claim 17, wherein the channel material continuously extends between neighboring ones of the gate structures at a first height over the lower source/drain contact and wherein the channel material is discontinuous between the neighboring ones of the gate structures at a second height over the lower source/drain contact, the second height being less than the first height.

19. The method of claim 17, further comprising:
forming a channel insulating material along the one or more interior surfaces of the channel material.

20. The method of claim 19, wherein the channel insulating material has one or more interior surfaces that form an air-gap directly over the lower source/drain contact.
